(19) United States
(12) Patent Application Publication
(10) Pub. No.: US 2010/0155794 A1
(43) Pub. Date: Jun. 24, 2010

(54) REWORK METHOD OF METAL STRUCTURE OF SEMICONDUCTOR DEVICE

(76) Inventor: Seung-Woo Son, Gangbuk-gu (KR)

Correspondence Address: SHERR & VAUGHN, PLLC, 620 HERNDON PARKWAY, SUITE 320, HERNDON, VA, 20170, US

(21) Appl. No.: 12/620,836

(22) Filed: Nov. 18, 2009

(30) Foreign Application Priority Data
Dec. 24, 2008 (KR) 10-2008-0133673

(51) Int. Cl. H01L 23/52; H01L 21/768; H01L 29/78

(52) U.S. Cl. 257/288; 438/643; 257/774; 257/E29.255; 257/E23.141; 257/E21.584

(57) ABSTRACT

A rework method of a metal structure and devices thereof. A rework method may include forming a first metal layer over an insulating layer having a contact plug, a metal interconnection layer over a first metal layer and/or a second metal layer over a metal interconnection layer. A rework method may include performing a first wet etch process to remove first and/or second metal layers, except for a portion below a metal interconnection layer, removing a metal interconnection layer through a second wet etch process and/or planarizing a remaining portion of a first metal layer and/or a surface of an insulating layer through a first planarization process. An increase of a size of a contact hole, for example due to an over exposure of a contact hole, may be minimized.

The present application claims priority under 35 U.S.C. 119 to Korean Patent Application No. 10-2008-0133673 (filed on Dec. 24, 2008) which is hereby incorporated by reference in its entirety.

### BACKGROUND

Embodiments relate to a rework method of a metal structure of a semiconductor device, and devices thereof.

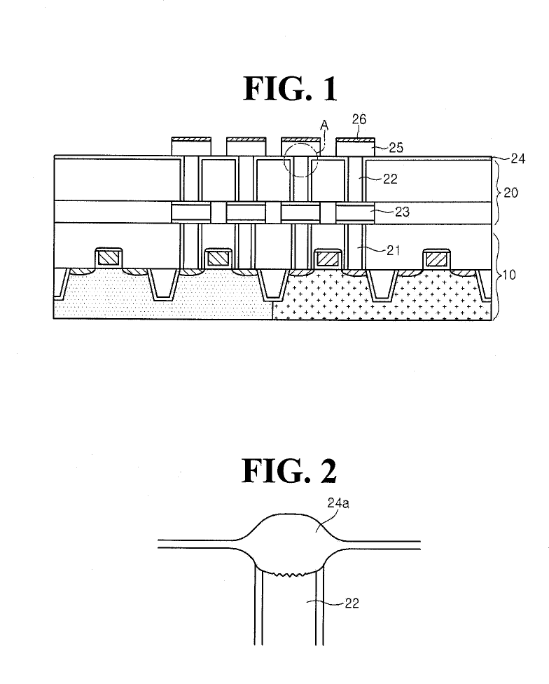

Referring to example FIG. 1, a sectional view illustrates a structure of a semiconductor device. Insulating layer 20 may include contact plug 21, contact plug 22 and/or metal interconnection 23. Insulating layer 20 may be formed on and/or over semiconductor substrate 10. Semiconductor substrate 10 may include an isolation layer, a source region, a drain region, a gate, a spacer and/or a gate insulating layer.

Insulating layer 20 may include a multi-layer structure. Each layer of a an insulating layer including a multi-layer structure may have a plurality of contact plugs 21,22 and/or metal interconnection 23, which may be longitudinally connected to each other. First metal layer 24, metal interconnection layer 25 and/or second metal layer 26 may be sequentially formed on and/or over insulating layer 20. First metal layer 20 and/or second metal layer 26 may include TiN. Metal interconnection layer 25 may include AlCu.

First metal layer 24, metal interconnection layer 25 and/or second metal layer 26 may be intermediate metal layers formed in the middle of a manufacturing process and/or may be top metal layers after a manufacturing process has been substantially finished. If defects occur in first metal layer 24, metal interconnection layer 25 and/or second metal layer 26, a rework process of a metal structure may be performed to strip and/or recover damaged layers. To perform a rework process of a metal structure, a surface of insulating layer 20 may be planarized through a chemical mechanical polishing (CMP) process, for example after striping a surface of second metal layer 26, metal interconnection layer 25 and/or first metal layer 24. A dry etch process may be used. Since loss of insulating layer 20 may be caused in a dry etch process and/or a planarization process, a process for compensating for a loss may be performed.

Referring to example FIG. 2, an enlarged view of part “A” shown in FIG. 1 is illustrated. An insulating layer inside contact plug 22 may be more deeply removed than other portions of insulating layer 20. Insulating layer 24a may be formed such that insulating layer 24a may include a relatively large thickness at a portion of contact plug 22. A CMP process may be performed with respect to insulating layer 24a to compensate for a loss of insulating layer 20. After compensating for a loss of insulating layer 20, metal materials may be stacked, patterned and/or etched to recover first metal layer 24, metal interconnection layer 25 and/or second metal layer 26.

However, as illustrated in FIG. 2, when a dry etch process and/or a planarization process may be performed, an insulating layer inside contact plug 22 may be more deeply etched and/or a contact hole may be over exposed. An upper portion of a contact hole may be widened. Compensation for a widened contact hole may be relatively difficult to achieve. Since a widened contact hole may minimize an electric characteristic and/or may make it difficult to rework a metal structure, a semiconductor wafer may be discarded.

Accordingly, there is a need of a rework method of a metal structure, and devices thereof, which may be capable of minimizing a size increase of a contact hole due to defects of a metal structure, for example from over exposure of a contact hole during a rework process.

### SUMMARY

Embodiments relate to a rework method of a metal structure, and devices thereof, which may be capable of minimizing a size increase of a contact hole from over exposure of a contact hole when performing a rework process, for example resulting from defects of a metal structure including a contact plug and/or a metal interconnection. According to embodiments, a rework method of a metal structure may include forming a first metal layer on and/or over an insulating layer having a contact plug, a metal interconnection layer on and/or over a first metal layer, and/or a second metal layer on and/or over a metal interconnection layer.

According to embodiments, a rework method of a metal structure may include performing a first wet etch process to remove a first and/or second metal layer, except for a portion below a metal interconnection layer. In embodiments, a rework method of a metal structure may include removing a metal interconnection layer through a second wet etch process. In embodiments, a rework method of a metal structure may include planarizing a remaining portion of a first metal layer and/or a surface of an insulating layer through a first planarization process.

### DRAWINGS

Example FIG. 1 is a side sectional view illustrating a structure of a semiconductor device.

Example FIG. 2 is an enlarged view of part “A” illustrated in FIG. 1. Example FIG. 3 is a sectional view illustrating a structure of a semiconductor device before a rework method of a metal structure may be performed in accordance with embodiments.

Example FIG. 4 is a sectional view illustrating a semiconductor device after a portion of first and second metal layers are removed through a rework method of a metal structure in accordance with embodiments.

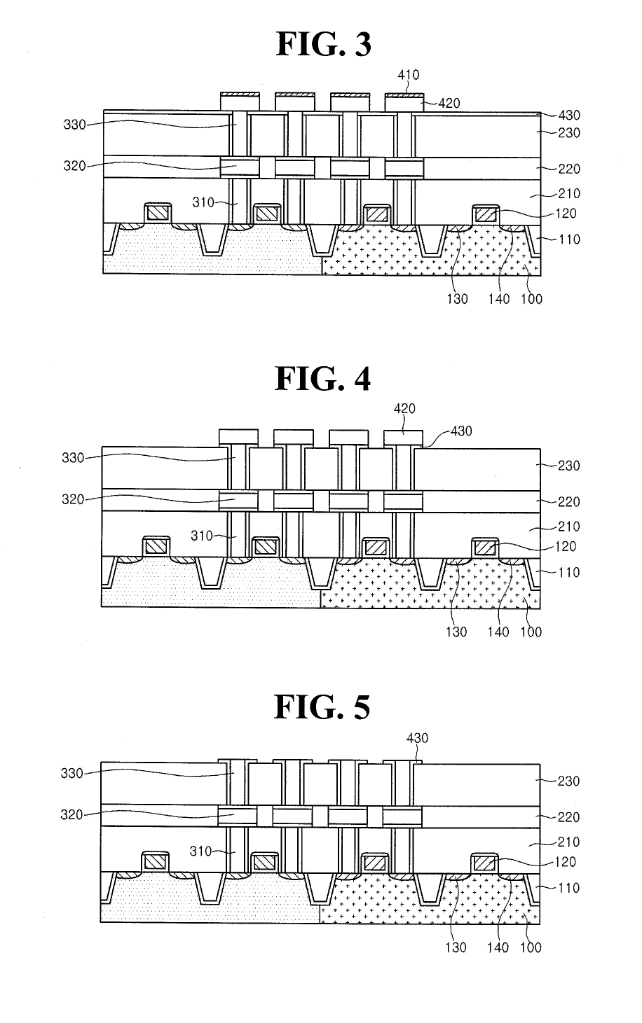

Example FIG. 5 is a sectional view illustrating a semiconductor device after a metal interconnection layer is removed through a rework method of a metal structure in accordance with embodiments.

### DESCRIPTION

Embodiments relate to a rework method of a metal structure, and devices thereof. Referring to example FIG. 3, a sectional view illustrates a structure of a semiconductor device before a rework method of a metal structure is performed in accordance with embodiments. FIG. 3 may illustrate a semiconductor device in the middle of a process for a metal interconnection layer, after a process for a metal interconnection layer has been performed, and/or after a semiconductor device layer has been formed.

According to embodiments, isolation layer 110 may be formed on and/or over semiconductor substrate 100. In embodiments, source region 130, drain region 140 and/or a light doped drain (LDD) region may be formed on and/or over an active region which may be defined by isolation layer 110. In embodiments, gate electrode 120, a gate insulating layer and/or a spacer may be formed on and/or over a surface of semiconductor substrate 100, which may correspond to an active region.

According to embodiments, insulating layers 210, 220 and/or 230 may be formed on and/or over a surface, which may be an entire surface, of semiconductor substrate 100 which may include gate electrode 120. In embodiments, a contact hole process, a gap-fill process, a metal layer deposition process, a patterning process and/or an etch process may be performed to form contact plugs 310,330 and/or metal interconnection 320 on and/or over insulating layers 210, 220 and/or 230. In embodiments, three layers of insulating layers 210, 220 and/or 230 may be employed, but embodiments are not limited thereto. In embodiments, insulating layers 210, 220 and/or 230 may include more or less than three layers. In embodiments, each layer may include contact plugs 310,330 and/or metal interconnection 320 longitudinally connected to each other.

According to embodiments, first metal layer 430 may be formed on and/or over insulating layer 230. In embodiments, patterned metal interconnection layer 420 may be formed on and/or over first metal layer 430. In embodiments, second metal layer 410 may be formed on and/or over metal interconnection layer 420. In embodiments, first metal layer 430 and/or second metal layer 410 may include TiN. In embodiments, metal interconnection layer 420 may include AlCu. In embodiments, first metal layer 430, metal interconnection layer 420 and/or second metal layer 410 may include intermediate metal layers formed in the middle of a metal interconnection layer process and/or top metal layers formed after a metal interconnection layer process has been finished.

If defects occur in first metal layer 430, the metal interconnection layer 420 and/or second metal layer 410, for example when a metal interconnection layer process may be performed and/or finished, a rework process of a metal structure may be performed to strip and/or recover damaged layers. Referring to example FIG. 4, a sectional view illustrates a semiconductor device after a portion of first metal layer 410 and/or second metal layer 430 may have been removed through a rework process of a metal structure in accordance with embodiments.

According to embodiments, a portion of first metal layer 410 and/or a portion of second metal layer 430 may be removed, for example through a first wet etch process. In embodiments a first wet etch process may employ a solution, for example in which hydrogen peroxide (H₂O₂) may be mixed with deionized water (DIW). In embodiments, H₂O₂ may be mixed with DIW at a volume ratio of between approximately 1:320 and 1:400 and used as an etch solution.

According to embodiments, metal interconnection layer 420 may be removed through a first wet etch process. In embodiments, metal interconnection layer 420 may be removed at a removal rate of approximately 15 Å/min through a first wet etch process. In embodiments, first metal layer 410 and/or second metal layer 430 may be removed at a removal rate of approximately 2050 Å/min. In embodiments, first metal layer 410 and/or second metal layer 430 may be removed through a first wet etch process. In embodiments, a portion of first metal layer 430 may remain below metal interconnection layer 420. In embodiments, a semiconductor device may include first metal layer 410 and/or second metal layer 430 as illustrated in FIG. 4.

Referring to example FIG. 5, a sectional view illustrates a semiconductor device after metal interconnection layer 420 may be removed through a rework process of a metal structure in accordance with embodiments. According to embodiments, metal interconnection layer 420 may be removed through a second wet etch process. In embodiments, a second wet etch process may employ a solution which may include nitric acid, acetic acid and/or phosphoric acid. In embodiments, nitric acid, acetic acid and phosphoric acid may be mixed with each other at a ratio of between approximately 1% and 5%:10% and 20%:60% and 75%, respectively.

According to embodiments, first metal layer 410 and/or second metal layer 430 may not be etched through a second wet etch process. In embodiments, metal interconnection layer 420 may be removed at a removal rate of approximately 3700 Å/min through a second wet etch process. In embodiments, metal interconnection layer 420 may be removed through a second wet etch process.

According to embodiments, a first planarization process may be performed with respect to a surface of insulating layer 230 together with a remaining portion of first metal layer 430. In embodiments, first and/or second wet etch processes may be performed including a predetermined etch selectivity. In embodiments, an upper portion of a contact hole of insulating layer 230 may be substantially prevented from excessively being exposed and/or widened.

According to embodiments, insulating layer 230 formed inside contact plug 330 may be more deeply removed than other portions of insulating layer 230. In embodiments, an insulating layer corresponding to contact plug 330 may be formed including a relatively thick thickness, and/or a loss of insulating layer inside contact plug 330 may be compensated by a second planarization process. In embodiments, first and/or second planarization processes may include a CMP process. In embodiments, a TiN layer and/or a AlCu layer may be stacked, patterned and/or etched, for example after a second planarization process may be performed. In embodiments, first metal layer 430, metal interconnection layer 420 and/or second metal layer 410 may be recovered.

According to embodiments, a rework process may be performed when defects may occur in a metal structure, including a contact plug and/or a metal interconnection, such that an increase in size of a contact hole due to an excessive exposure of the contact hole may be substantially prevented. In embodiments, a size of a contact hole may be substantially uniformly maintained, such that a probability of success of a rework process may be maximized. In embodiments, discarding a semiconductor wafer may be minimized, such that manufacturing cost and/or time may be reduced.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first metal layer over an insulating layer having a contact plug, a metal interconnection layer over said first metal layer, and a second metal layer over said metal interconnection layer;
performing a first wet etch process to remove said first and said second metal layers, excluding a portion of said first metal layer below said metal interconnection layer;
performing a second wet etch process to remove said metal interconnection layer; and
performing a first planarization process to planarize at least one of said excluded portion of said first metal layer and a surface of said insulating layer.

2. The method of claim 1, wherein said first wet etch process comprises a mixture of hydrogen peroxide water and deionized water as an etch solution.

3. The method of claim 2, wherein said hydrogen peroxide water and deionized water comprise a volume ratio between approximately 1:320 and 1:400.

4. The method of claim 1, wherein said second wet etch process comprises nitric acid, acetic acid and phosphoric acid.

5. The method of claim 4, wherein said nitric acid, acetic acid and phosphoric acid comprise a ratio between approximately 1% and 5%:10% and 20%:60% and 75%.

6. The method of claim 1, comprising:
depositing a compensation insulating layer over said insulating layer corresponding to said contact plug; and
performing a second planarization process with respect to said compensation insulating layer.

7. The method of claim 1, comprising recovering at least one of said first metal layer, said metal interconnection layer and said second metal layer by performing at least one of depositing, patterning and etching of a metal material.

8. The method of claim 1, wherein said insulating layer is formed over a semiconductor substrate comprising at least one of an isolation layer, a gate electrode, a gate insulating layer, a source region and a drain region.

9. The method of claim 1, wherein said insulating layer comprises a multi-layer structure.

10. The method of claim 9, wherein each layer of said insulating layer comprises a lower metal structure having contact plugs and a metal interconnection, which are longitudinally connected to each other.

11. The method of claim 1, wherein at least one of said first metal layer and said second metal layer comprise TiN.

12. The method of claim 1, wherein said metal interconnection layer comprises AlCu.

13. The method of claim 1, wherein said first metal layer, said metal interconnection layer and said second metal layer comprise at least one of:
a lower metal interconnection;
an intermediate metal interconnection; and
an upper metal interconnection.

14. An apparatus comprising:
a planarized first metal layer over an insulating layer having a contact plug,
wherein said planarized first metal layer is formed from a first metal layer which is etched by a first wet etching process such that a portion of said first metal layer remains under a metal interconnection layer and which is unetched in a second wet etching process to remove said metal interconnection layer, said remaining first metal layer planarized to form said planarized first metal layer.

15. The apparatus of claim 14, wherein at least one of:
said first wet etch process comprises hydrogen peroxide and deionized water at a volume ratio between approximately 1:320 and 1:400; and
said second wet etch process comprises nitric acid, acetic acid and phosphoric acid at a ratio between approximately 1% and 5%:10% and 20%:60% and 75%.

16. The apparatus of claim 14, comprising a planarized compensation insulating layer over said insulating layer corresponding to said contact plug.

17. The apparatus of claim 14, wherein at least one of said first metal layer, said metal interconnection layer and a second metal layer are recovered.

18. The apparatus of claim 14, wherein said insulating layer is formed over a semiconductor substrate comprising at least one of an isolation layer, a gate electrode, a gate insulating layer, a source region and a drain region.

19. The apparatus of claim 14, wherein:
said insulating layer comprises a multi-layer structure; and
each layer of said insulating layer comprises a lower metal structure having contact plugs and a metal interconnection, which are longitudinally connected to each other.

20. The apparatus of claim 14, wherein said first metal layer, said metal interconnection layer and a second metal layer comprise at least one of:
a lower metal interconnection;
an intermediate metal interconnection; and
an upper metal interconnection.
